(19) United States
(12) Patent Application Publication
(10) Pub. No.: US 2025/0143142 A1
(43) Pub. Date: May 1, 2025

(54) DISPLAY DEVICE INCLUDING QUANTUM-DOT LIGHT EMITTING DEVICE AND MANUFACTURING METHOD THEREOF

(71) Applicant: Samsung Display Co., LTD., Yongin-si (KR)

(72) Inventors: Jongjang PARK, Yongin-si (KR); Dongjin KANG, Yongin-si (KR); Soo Hyun PARK, Yongin-si (KR); Seok Soon BACK, Yongin-si (KR); Dongha LEE, Yongin-si (KR)

(21) Appl. No.: 18/742,642

(22) Filed: Jun. 13, 2024

(30) Foreign Application Priority Data
Oct. 30, 2023 (KR) 10-2023-0146341

(51) Int. Cl. H10K 59/80; H10K 50/115; H10K 59/12

(52) U.S. Cl. CPC H10K 59/873; H10K 50/115; H10K 59/1201

(57) ABSTRACT

A method of manufacturing a display device and a display device are provided. The method of manufacturing a display device includes manufacturing a display panel including a plurality of quantum-dot light emitting devices, exposing the display panel to resin fumes, and adhering a protective layer on the display panel.

### CROSS-REFERENCE TO RELATED APPLICATION

The present application claims priority to and the benefit of Korean Patent Application No. 10-2023-0146341, filed on Oct. 30, 2023, in the Korean Intellectual Property Office, the entire content of which is hereby incorporated by reference.

### BACKGROUND

### 1. Field

Embodiments of the present disclosure relate to a method of manufacturing a display device, and, for example, to a method of manufacturing a display device including a quantum-dot light emitting device.

### 2. Description of the Related Art

Unlike bulk materials, nanoparticles have physical properties (e.g., energy band gap, melting point, and/or the like), that are intrinsic properties of the nanoparticles, and which may vary depending on the particle size.

For example, semiconductor nanocrystals, also called quantum dots, may be to emit light with a wavelength (e.g., a certain wavelength), and the wavelength may correspond to the size of the quantum dots upon receiving the light energy or electrical energy.

Accordingly, quantum dots may be utilized as light emitters that emit light with a set or predetermined wavelength.

### SUMMARY

Aspects of one or more embodiments of the present disclosure relate to a quantum-dot light emitting device that may improve performance of a display device.

Aspects of one or more embodiments of the present disclosure relate to a method of manufacturing the quantum-dot light emitting device.

Additional aspects will be set forth in part in the description which follows and, in part, will be apparent from the description, or may be learned by practice of the presented embodiments of the disclosure.

A method of manufacturing a display device according to one or more embodiments of the present disclosure includes manufacturing a display panel including a plurality of quantum-dot light emitting devices, exposing the display panel to resin fumes, and adhering a protective layer on the display panel.

In one or more embodiments, the resin fumes may include at least one of acrylic acid, acetic acid, methacrylic acid, and/or isobornyl methacrylate.

In one or more embodiments, the resin fumes may include at least one of acrylic acid and/or methacrylic acid.

In one or more embodiments, the protective film may include a transparent glass.

In one or more embodiments, the protective film may be attached to the display panel by a sealant arranged adjacent to an edge one of the display panel and/or the protective film.

A display device according to one or more embodiments of the present disclosure includes a display panel including a plurality of quantum-dot light emitting devices, the display panel including a resin adsorbed on the quantum-dot light emitting devices via resin fumes (e.g., the resin adsorbed on the quantum-dot light emitting devices is a fume adsorbed resin), a protective film on the display panel, and a sealant arranged between the display panel and the protective film and adjacent to edges of the display panel and the protective film.

In one or more embodiments, the resin fumes may include at least one of acrylic acid, acetic acid, methacrylic acid, and/or isobornyl methacrylate.

In one or more embodiments, the resin fumes may include at least one of acrylic acid and/or methacrylic acid.

In one or more embodiments, the protective film may include a transparent glass.

In one or more embodiments, the quantum-dot light emitting devices may each include an electron auxiliary layer surface-modified with the resin.

A method of manufacturing a display device according to one or more embodiments of the present disclosure includes manufacturing a display panel including a plurality of quantum-dot light emitting devices, exposing the display panel to resin fumes, and sealing the display panel with a sealant.

In one or more embodiments, the resin fumes may include at least one of acrylic acid, acetic acid, methacrylic acid, and/or isobornyl methacrylate.

In one or more embodiments, the resin fumes may include at least one of acrylic acid and/or methacrylic acid.

In one or more embodiments, the sealing of the display panel may include adhering a protective film on the display panel.

A display device according to one or more embodiments of the present disclosure includes a display panel including a plurality of quantum-dot light emitting devices, a protective film on the display panel, and a sealant between the display panel and the protective film and adjacent to edges of the display panel and the protective film, wherein the display panel and the protective film are spaced from each other via an air layer.

In one or more embodiments, the display panel may include a resin adsorbed on the quantum-dot light emitting devices via resin fumes.

In one or more embodiments, the resin fumes may include at least one of acrylic acid, acetic acid, methacrylic acid, and/or isobornyl methacrylate.

In one or more embodiments, the resin fumes may include at least one of acrylic acid and/or methacrylic acid.

In one or more embodiments, the protective film may include a transparent glass.

In one or more embodiments, the quantum-dot light emitting devices may each include an electron auxiliary layer surface-modified with the resin.

According to one or more embodiments of the present disclosure, the performance of a display device including a quantum-dot light emitting device may be improved.

### BRIEF DESCRIPTION OF THE DRAWINGS

FIG. 1 is a schematic cross-sectional view of a display device according to one or more embodiments of the present disclosure.

FIG. 2 is a schematic view showing the manufacturing process of a display device according to one or more embodiments of the present disclosure.

FIG. 3 is a graph showing the change in characteristics of a red pixel as a function of sputtering time in an example of the present disclosure.

FIG. 4 is a graph showing the change in characteristics of a blue pixel as a function of sputtering time in an example of the present disclosure.

FIG. 5 is a graph showing the change in characteristics of a green pixel as a function of sputtering time in an example of the present disclosure.

FIG. 6 is a schematic cross-sectional view of a quantum-dot light emitting device in a display panel according to one or more embodiments of the present disclosure.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

Hereinafter, example embodiments will be described in more detail with reference to the accompanying drawings. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

In order to clearly explain the present disclosure, parts not related to the description have not been provided, and identical or similar components may be given the same reference numerals throughout the specification. Unless otherwise noted, like reference numerals denote like elements throughout the attached drawings and the written description, and thus, duplicative descriptions thereof may not be provided.

Additionally, the size and thickness of each part shown in the drawings may be exaggerated for convenience of explanation, so the present disclosure is not limited thereto. In particular, in the drawings, the thickness may be enlarged and exaggerated to clearly express various layers and areas and to facilitate explanation.

It will be understood that when an element, such as a layer, film, region, plate or substrate, is referred to as being “on,” or “above” another element, it can be directly on or above the other element, or one or more intervening elements may be present. In addition, it will also be understood that when an element is referred to as being “between” two elements, it can be the only element between the two elements, or one or more intervening elements may also be present. Conversely, if (e.g., when) an element is referred to as being “directly on,” “directly above,” or “right on top” of another element, then there are no intervening elements in-between.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

Spatially relative terms, such as “on,” “above,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

It will be further understood that the terms “comprises,” “comprising,” “includes,” “including,” “have,” and “having,” when used in this specification, specify the presence of the stated features, integers, steps, operations, elements, and/or components, but do not preclude the presence or addition of one or more other features, integers, steps, operations, elements, components, and/or groups thereof.

As used herein, the singular forms “a,” “an” and “the” are intended to include the plural forms as well, unless the context clearly indicates otherwise.

As used herein, the term “and/or” includes any and all combinations of one or more of the associated listed items. Unless otherwise apparent from the disclosure, expressions such as “at least one of,” “a plurality of,” “one of,” and other prepositional phrases, when preceding a list of elements, should be understood as including the disjunctive if written as a conjunctive list and vice versa. For example, the expressions “at least one of a, b, or c,” “at least one of a, b, and/or c,” “one selected from the group consisting of a, b, and c,” “at least one selected from a, b, and c,” “at least one from among a, b, and c,” “one from among a, b, and c”, “at least one of a to c” indicates only a, only b, only c, both a and b, both a and c, both b and c, all of a, b, and c, or variations thereof.

In the present disclosure, when particles are spherical, “diameter or size” indicates a particle diameter or an average particle diameter, and when the particles are non-spherical, the “diameter or size” indicates a major axis length or an average major axis length. The diameter (or size) of the particles may be measured utilizing a scanning electron microscope or a particle size analyzer. As the particle size analyzer, for example, HORIBA, LA-950 laser particle size analyzer, may be utilized. When the size of the particles is measured utilizing a particle size analyzer, the average particle diameter (or size) is referred to as D50. D50 refers to the average diameter (or size) of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size.

In addition, throughout the specification, if (e.g., when) reference is made to “on a plane,” this refers to when the target portion is viewed from above, and when reference is made to “in a cross-section,” this refers to when a cross-section of the target portion is cut vertically and viewed from the side.

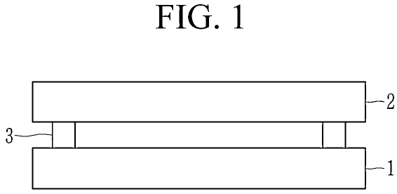

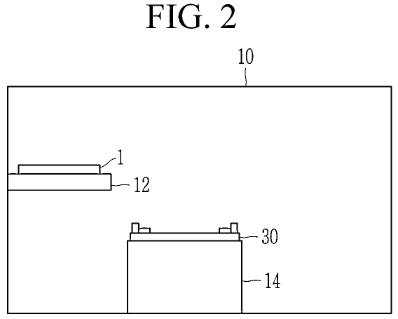

First, a display device according to one or more embodiments of the present disclosure will be described in more detail with reference to FIGS. 1 and 2.

FIG. 1 is a schematic cross-sectional view of a display device according to one or more embodiments of the present disclosure, and FIG. 2 is a schematic view showing a manufacturing process of a display device according to one or more embodiments of the present disclosure.

Referring to FIG. 1, a display device according to one or more embodiments of the present disclosure may include a display panel 1 and a protective film 2, and a sealant 3 arranged near (e.g., adjacent) the edge between the display panel 1 and the protective film 2.

There is no separate encapsulation resin between the display panel 1 and the protective film 2 so that the display panel 1 and the protective film 2 may be in direct contact or spaced apart via an air layer.

The display panel 1 may include a plurality of quantum-dot light emitting devices, and may display images by controlling the emission of the light emitting devices.

The protective film 2 may include transparent glass, and/or the like, and may be attached to the display panel 1 through the sealant 3.

There may be a space between the display panel 1 and the protective film 2.

In order to manufacture such a display device, the display panel 1 including a plurality of quantum-dot light emitting devices may be first manufactured and then exposed to resin fumes to be coated with resin.

This process may be performed in a closed space. For example, referring to FIG. 2, a dispenser 14 that emits resin fumes may be installed on the floor in a closed space 10, and the display panel 1 may be installed and a support 12 on which a display panel 1 may be placed, may be installed on the side wall of the closed space 10.

Afterwards, the manufactured display panel 1 may be placed on the support 12, and an auxiliary panel 30 coated with resin may be placed on the dispenser 14. The display panel 1 may be left until an appropriate or suitable amount of resin is adsorbed on the display panel 1 (e.g., the resin adsorbed on the display panel 1 (e.g., the resin adsorbed on the quantum-dot light emitting devices) is a fume adsorbed resin).

Resin fumes may include acrylic acid, acetic acid, methacrylic acid, isobornyl methacrylate, and/or the like.

Acrylic acid and methacrylic acid components may improve the characteristics of electron transport layers of quantum-dot light emitting devices of the display panel 1 by filling the oxygen vacancy of the metal oxide (e.g., zinc-metal-oxide (ZMO)) of the quantum-dot light emitting devices (e.g., the resin is adsorbed on (onto) surfaces of metal oxide nanoparticles (in nanometer scale) utilized in electron transport layers of a quantum-dot light emitting device 100, such that the metal oxide nanoparticles are surface-modified with the resin, as described in more detail below).

In addition, as the quantum dot-light emitting devices may be oxidized by these acid components, a vacuum level shift may occur and thus the electronic barrier may be reduced, thereby improving the characteristics of the electron transport layers.

After leaving the display panel 1 in resin fumes in the closed space as described above for an appropriate or suitable period of time, a protective film 2 may be attached to the surface of the display panel 1 utilizing a sealant 3, thereby completing a display device.

At this time, a separate encapsulation resin may not be utilized between the display panel 1 and the protective film 2 so that the stains that may appear on the display device due to the encapsulation resin may be suppressed or reduced.

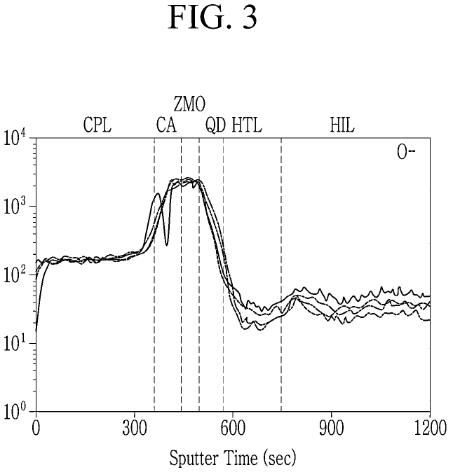

Now, comparative examples and experimental examples of the present disclosure will be described in more detail with reference to FIGS. 3 to 5.

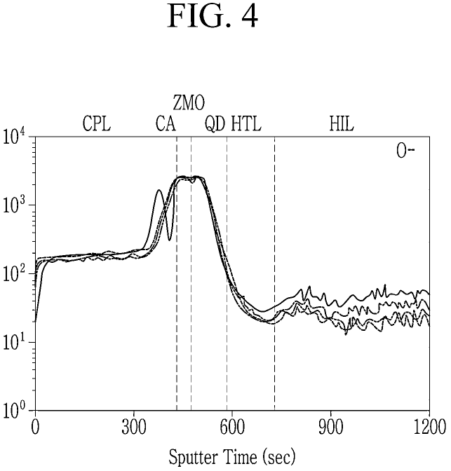

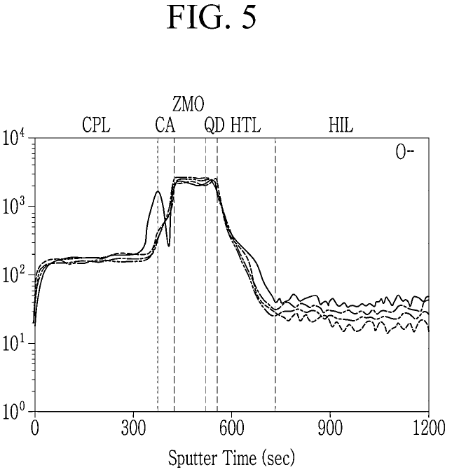

FIG. 3 is a graph showing the change in characteristics of a red pixel as function of sputtering time in an example of the present disclosure, FIG. 4 is a graph showing the change in characteristics of a blue pixel as function of sputtering time in an example of the present disclosure, and FIG. 5 is a graph showing the change in characteristics of a green pixel as function of sputtering time in an example of the disclosure.

In a comparative example, a drop of sealing resin was dripped on the surface of the manufactured display panel, then a protective film was placed and pressed so that the resin may be spread evenly over the surface.

As a result, the desired or suitable device characteristics were not obtained, or spots appeared on the display panel even if the desired or suitable device characteristics were obtained.

However, in the case of display devices manufactured according to embodiments of the manufacturing method as described above, not only were the device characteristics obtained and the efficiency increased, but no stain appeared, as shown in FIGS. 3 to 5.

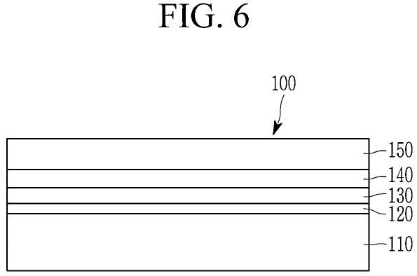

Now, with reference to FIG. 6, an example of a quantum-dot light emitting device in a display panel according to one or more embodiments of the present disclosure will be described in more detail.

FIG. 6 is a schematic cross-sectional view of a quantum-dot light emitting device 100 in a display panel according to one or more embodiments of the present disclosure.

Referring to FIG. 6, a quantum-dot light emitting device 100 may include a first electrode 110 and a second electrode 150 facing each other, a light emitting layer 130 arranged between the first electrode 110 and the second electrode 150 and including quantum dots, a hole auxiliary layer 120 arranged between the first electrode 110 and the light emitting layer 130, and an electron auxiliary layer 140 arranged between the second electrode 150 and the light emitting layer 130.

A substrate may be placed on an outer side either of the first electrode 110 or of the second electrode 150.

As an example, the substrate may be placed on the outer side of the first electrode 110.

1 The substrate may be a substrate including an insulating material (e.g., an insulating transparent substrate).

The substrate may include one or more of (e.g., one or more selected from among): glass; one or more suitable polymers such as polyesters (e.g., polyethylene terephthalate (PET), and/or polyethylene naphthalate (PEN)), polycarbonate, polyacrylate, polyimide, polyamideimide, and/or the like; polysiloxane (e.g., PDMS); inorganic materials such as Al₂O₃, ZnO, and/or the like; and/or any suitable combination thereof. But the present disclosure is not limited thereto.

The substrate may include a silicon wafer and/or the like.

The thickness of the substrate may be appropriately or suitably selected in consideration of the substrate material, and/or the like, and the present disclosure is not particularly limited.

The transparent substrate may be flexible.

In one or more embodiments, the substrate may not be provided.

One of the first electrode 110 or the second electrode 150 is an anode and the other is a cathode. For example, the first electrode 110 may be an anode and the second electrode 150 may be a cathode.

The first electrode 110 may include a conductor, such as a metal, a conductive metal oxide, and/or any suitable combination thereof.

The first electrode 110 may include a metal such as nickel, platinum, vanadium, chromium, copper, zinc, and gold, or an alloy thereof; a conductive metal oxide such as zinc oxide, indium oxide, tin oxide, indium tin oxide (ITO), indium zinc oxide (IZO), or fluorine-doped tin oxide; and/or any suitable combination of metal and oxide such as Al and ZnO or Sb and SnO₂, but the present disclosure is not be limited thereto.

As an example, the first electrode 110 may include a transparent conductive metal oxide, such as indium tin oxide (ITO).

1 The second electrode 150 may include a conductor, for example, a metal, a conductive metal oxide, and/or a conductive polymer.

The second electrode 150 may include a metal such as Al, Mg, Ca, Na, Ka, Ti, In, Y, Li, Gd, Ag, Sn, Pb, Cs, Ba, and/or the like, or an alloy thereof; and/or a multilayered material such as LiF/Al, LiO₂/Al, Liq/Al, LiF/Ca, and/or BaF₂/Ca, but the present disclosure is not be limited thereto.

Examples of the conductive metal oxide may include those listed above with reference to the first electrode.

At least one of the first electrode 110 and/or the second electrode 150 may be a light transmitting electrode, and the light transmitting electrode may include a conductive metal oxide, for example, zinc oxide, indium oxide, tin oxide, indium tin oxide (ITO), or indium zinc oxide (IZO), and may include a single-layered thin film or a multi-layered metal thin film.

When either the first electrode 110 or the second electrode 150 is a non-transmissive electrode, it may include an opaque conductor such as Al, Ag, or Au.

The thickness of the first electrode 110 and/or the second electrode 150 may not be particularly limited and may be appropriately or suitably selected in consideration of device efficiency.

For example, the thickness of the first electrode 110 or the second electrode 150 may be about 5 nanometers (nm) or more, for example, about 50 nm or more.

For example, the thickness of the first electrode 110 or the second electrode 150 may be about 100 micrometers (μm) or less, such as about 10 μm or less, or about 1 μm or less, about 900 nm or less, about 500 nm or less, or about 100 nm or less.

The light emitting layer 130 may include a plurality of quantum dots. The quantum dots (hereinafter also referred to as “semiconductor nanocrystals”) may include a Group II-VI compound, a Group III-V compound, a Group IV-VI compound, a Group IV element or compound, a Group I-III-VI compound, and/or a Group I-II-IV-VI compound of the Periodic Table of Elements, and/or any suitable combination thereof.

The Group II-VI compound may be (e.g., may be selected from among) a group including: a binary compound of (e.g., selected from among) the group including (e.g., consisting of) CdSe, CdTe, ZnS, ZnSe, ZnTe, ZnO, HgS, HgSe, HgTe, MgSe, MgS and/or any suitable mixture thereof; a ternary compound of (e.g., selected from among) the group including (e.g., consisting of) CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS and/or any suitable mixture thereof; and/or a quaternary compound of (e.g., selected from among) the group including (e.g., consisting of) HgZnTeS, CdZnSeS, CdZnSeTe, CdZnSTe, CdHgSeS, CdHgSeTe, CdHgSTe, HgZnSeS, HgZnSeTe, HgZnSTe and/or any suitable mixture thereof. Group II-VI compounds may further include a Group Ill metal.

The Group III-V compound may be (e.g., may be selected from among) a group including: a binary compound of (e.g., selected from among) a group including (e.g., consisting of) GaN, GaP, GaAs, GaSb, AlN, AIP, AlAs, AlSb, InN, InP, InAs, InSb, and/or any suitable mixture thereof; a ternary compound of (e.g., selected from among) a group including (e.g., consisting of) GaNP, GaNAs, GaNSb, GaPAs, GaPSb, AlNP, AlNAs, AlNSb, AlPAS, AlPSb, InNP, InNAs, InNSb, InPAs, InPSb, and/or any suitable mixture thereof; and/or a quaternary compound of (e.g., selected from among) a group including (e.g., consisting of) GaAlNP, GaAlNAs, GaAlNSb, GaAlPAs, GaAlPSb, GalnNP, GalnNAs, GalnNSb, GalnPAs, GalnPSb, InAlNP, InAlNAs, InAlNSb, InAlPAs, InAlPSb, InZnP, and/or any suitable mixture thereof. The Group III-V compound may further include a Group II metal (e.g., InZnP).

The Group IV-VI compound may be of (e.g., may be selected from among) a group including: a binary compound of (e.g., selected from among) the group including (e.g., consisting of) SnS, SnSe, SnTe, PbS, PbSe, PbTe, and/or any suitable mixture thereof; a ternary compound of (e.g., selected from among) the group including (e.g., consisting of) SnSeS, SnSeTe, SnSTe, PbSeS, PbSeTe, PbSTe, SnPbS, SnPbSe, SnPbTe, and/or any suitable mixture thereof; and/or a quaternary compound of (e.g., selected from among) the group including (e.g., consisting of) SnPbSSe, SnPbSeTe, SnPbSTe, and/or any suitable mixture thereof.

Examples of the Group I-III-VI compound may include, but are not limited to, CulnSe₂, CulnS₂, CulnGaSe, and CulnGaS.

Examples of the Group I-II-IV-VI compound include, but are not limited to, CuZnSnSe, and CuZnSnS.

The Group IV element or compound may be (e.g., may be selected from among) a group including: a single element of (e.g., selected from among) the group including (e.g., consisting of) Si, Ge, and/or any suitable mixture thereof; and/or a binary compound of (e.g., selected from among) the group including (e.g., consisting of) SiC, SiGe, and/or any suitable mixture thereof.

According to one or more embodiments of the present disclosure, the quantum dots may not include (e.g., may exclude) cadmium.

The quantum dots may include a semiconductor nanocrystal based on a Group III-V compound including indium and phosphorus.

The Group III-V compound may further include zinc.

The quantum dots may include a semiconductor nanocrystal based on a Group II-VI compound including a chalcogen element (e.g., S, Se, Te, and/or any suitable combination thereof) and zinc.

In quantum dots, the above-mentioned binary compound, ternary compound, and/or quaternary compound may be distributed in a substantially uniform concentration in a semiconductor nanocrystal, or may be grouped into parts with different concentrations at different regions of the semiconductor nanocrystal.

The semiconductor nanocrystal may have a core/shell structure in which a first semiconductor nanocrystal (core) may be surrounded by a second semiconductor nanocrystal (shell) having a composition that is the same as or different from the first semiconductor nanocrystal.

As an example, the quantum dots may include a core including InP, InZnP, ZnSe, ZnSeTe, and/or any suitable combination thereof, and a shell (or a multi-layered shell) having a different composition from the core and including InP, InZnP, ZnSe, ZnS, ZnSeTe, ZnSeS, and/or any suitable combination thereof.

The interface between the core and the shell may have a concentration gradient in which the concentration of elements present in the shell decreases toward the center (e.g., the center of the core).

Additionally, a semiconductor nanocrystal may have a structure including a single semiconductor nanocrystal core and a multi-layered shell around (e.g., surrounding) the core. In such embodiments, the multi-layered shell may include two or more layers, and each layer may have a single composition, an alloy, or a gradient concentration composition.

In the quantum dots, the shell material and the core material may have different energy band gaps. For example, the energy band gap of the shell material may be larger than that of the core material. In one or more embodiments, the energy band gap of the shell material may be smaller than that of the core material.

The quantum dots may have a multilayered shell. In a multilayered shell, the energy band gap of an outer layer may be larger than that of an inner layer (i.e., a layer closer to the core). In a multilayered shell, the energy band gap of an outer layer may be smaller than that of an inner layer.

The absorption/emission wavelengths of the quantum dots may be adjusted by changing the composition and size the quantum dots. The maximum emission peak wavelength of the quantum dots may range from ultraviolet to infrared wavelengths or longer. For example, the maximum emission peak wavelength of the quantum dots may be equal to or greater than about 300 nm, such as about 500 nm or more, about 510 nm or more, about 520 nm or more, about 530 nm or more, about 540 nm or more, about 550 nm or more, about 560 nm or more, about 570 nm or more, about 580 nm or more, about 590 nm or more, about 600 nm or more, or about 610 nm or more.

The maximum emission wavelength of the quantum dots may be in a range to about 800 nm or less, such as about 650 nm or less, about 640 nm or less, about 630 nm or less, about 620 nm or less, about 610 nm or less, about 600 nm or less, about 590 nm or less, about 580 nm or less, about 570 nm or less, about 560 nm or less, about 550 nm or less, or about 540 nm or less. The maximum emission wavelength of the quantum dots may be in a range of from about 500 nm to about 650 nm. The maximum emission wavelength of the quantum dots may be in a range of from about 500 nm to about 540 nm. The maximum emission wavelength of quantum dots may be in a range of from about 610 nm to about 640 nm.

The quantum dots may have quantum efficiency of equal to or greater than about 10%, such as about 30% or more, about 50% or more, about 60% or more, about 70% or more, about 90% or more, or even about 100%.

The quantum dots may have a relatively narrow spectrum. The quantum dots may have a full width at half maximum of the emission wavelength spectrum of, for example, equal to or less than about 50 nm, such as about 45 nm or less, about 40 nm or less, or about 30 nm or less.

The quantum dots may have a particle size (e.g., an average diameter) of equal to or greater than about 1 nm and equal to or less than about 100 nm. The quantum dots may have a size from about 1 nm to about 20 nm, such as at least about 2 nm, at least about 3 nm, or at least about 4 nm, and at most about 50 nm, at most about 40 nm, at most about 30 nm, at most about 20 nm, or at most about 15 nm, such as at least about 10 nm.

The shape of the quantum dots is not particularly limited. For example, the example shapes of the quantum dots may include, but is not limited to, a sphere, polyhedron, pyramid, multipod, square, cuboid, nanotube, nanorod, nanowire, nanosheet, or any suitable combination thereof.

The quantum dots may be commercially available or appropriately or suitably synthesized.

The particle size of the quantum dots may be adjusted relatively freely during colloid synthesis, and the particle size may be substantially uniform.

The quantum dots may include, for example, organic ligands having hydrophobic moieties. Organic ligand moieties may be bound to the surface of quantum dots. Organic ligands may include RCOOH, RNH2, R2NH, R3N, RSH, R3PO, R3P, ROH, RCOOR, RPO(OH)2, RHPOOH, R2POOH, and/or any suitable combination thereof, where each R may be independently a substituted or unsubstituted aliphatic hydrocarbon group from C3 (or C5) to C24 such as C3 (or C5) to C24 alkyl, alkenyl, and/or the like, a substituted or unsubstituted aromatic hydrocarbon group from C6 to C20 such as aryl groups from C6 to C20, and/or the like, and/or any suitable combination thereof.

Examples of organic ligands may include: a thiol compound such as methane thiol, ethane thiol, propane thiol, butane thiol, pentane thiol, hexane thiol, octane thiol, dodecane thiol, hexadecane thiol, octadecane thiol, benzyl thiol, and/or the like; an amine such as methane amine, ethane amine, propane amine, butane amine, pentyl amine, hexyl amine, octyl amine, nonyl amine, decyl amine, dodecyl amine, hexadecyl amine, octadecyl amine, dimethyl amine, diethyl amine, dipropyl amine, tributylamine, trioctylamine, and/or the like; a carboxylic acid compound such as methanoic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, benzoic acid, and/or the like; a phosphine compound such as methyl phosphine, ethyl phosphine, propyl phosphine, butyl phosphine, pentyl phosphine, octyl phosphine, dioctyl phosphine, tributyl phosphine, trioctyl phosphine, and/or the like; phosphine oxide such as methyl phosphine oxide, ethyl phosphine oxide, propyl phosphine oxide, butyl phosphine oxide, pentyl phosphine oxide, tributyl phosphine oxide, octyl phosphine oxide, dioctyl phosphine oxide, trioctyl phosphine oxide, and/or the like; diphenyl phosphine, triphenyl phosphine compounds or their oxide compounds; C5 to C20 alkyl phosphonic acids, C5 to C20 alkyl phosphonic acids such as hexylphosphonic acid, octylphosphonic acid, dodecanephosphonic acid, tetradecanephosphonic acid, hexadecanephosphonic acid, and/or octadecanephosphonic acid, but the present disclosure is not limited thereto.

The quantum dots may include a hydrophobic organic ligand alone or in any suitable mixture thereof. The hydrophobic organic ligand may not include (e.g., may exclude) a photopolymerizable residue, such as an acrylate group or a methacrylate group.

As an example, the light emitting layer 130 may include a monolayer of quantum dots. In one or more embodiments, the light emitting layer 130 may include one or more monolayers of the quantum dots, for example, at least two, three, or four monolayers and at most twenty, ten, nine, eight, seven or six monolayers.

The light emitting layer 130 has a thickness of equal to or greater than about 5 nm, such as about 10 nm or more, about 20 nm or more, or about 30 nm or more and equal to or less than about 200 nm, such as about 150 nm or less, about 100 nm or less, about 90 nm or less, about 80 nm or less, about 70 nm or less, about 60 nm or less, or about 50 nm or less. The light emitting layer 130 may have a thickness of, for example, from about 10 nm to about 150 nm, such as from about 10 nm to about 100 nm, or from about 10 nm to about 50 nm.

The light emitting layer 130 may have a highest occupied molecular orbital (HOMO) energy level of about 5.4 eV or more, about 5.6 eV or more, about 5.7 eV or more, about 5.8 eV or more, about 5.9 eV or more, or about 6.0 eV or more. The HOMO energy level of the light emitting layer 130 may be about 7.0 eV or less, about 6.8 eV or less, about 6.7 eV or less, about 6.5 eV or less, about 6.3 eV or less, or about 6.2 eV or less. As an example, the light emitting layer 130 may have a HOMO energy level of from about 5.6 eV to about 6.0 eV.

1 The light emitting layer 130 may have a least unoccupied molecular orbital (LUMO) energy level of equal to or less than about 3.8 eV, for example, about 3.7 eV or less, about 3.6 eV or less, about 3.5 eV or less, about 3.4 eV or less, about 3.3 eV or less, about 3.2 eV or less, or about 3.0 eV or less. The LUMO energy level of the light emitting layer 130 may be equal to or higher than about 2.5 eV. As an example, the light emitting layer 130 may have an energy band gap of from about 2.4 eV to about 2.9 eV.

As shown, for example, in FIG. 6, the hole auxiliary layer 120 may be arranged between the first electrode 110 and the light emitting layer 130. The hole auxiliary layer 120 may have one or two or more layers, and may include, for example, a hole injection layer, a hole transport layer, and/or an electron blocking layer.

The HOMO energy level of the hole auxiliary layer 120 may have a HOMO energy level that can match the HOMO energy level of the light emitting layer 130, and the mobility of holes transferred from the hole auxiliary layer 120 to the light emitting layer 130 may be enhanced. The HOMO energy level of the hole auxiliary layer (e.g., hole transport layer) 120 adjacent to the light emitting layer 130 may be equal to or smaller than the HOMO energy level of the light emitting layer 130 by at most about 1.0 eV. For example, the difference in HOMO energy levels between the hole auxiliary layer 120 and the light emitting layer 130 may be from about 0 eV to about 1.0 eV, from about 0.01 eV to about 0.8 eV, for example, from about 0.01 eV to about 0.7 eV, from about 0.01 eV to about 0.5 eV, from about 0.01 eV to about 0.4 eV, from about 0.01 eV to about 0.3 eV, from about 0.01 eV to about 0.2 eV, or from about 0.01 eV to about 0.1 eV.

The HOMO energy level of the hole auxiliary layer 120 may be equal to or higher than about 5.0 eV, for example, about 5.2 eV or more, about 5.4 eV or more, about 5.6 eV or more, or about 5.8 eV or more. The HOMO energy level of the hole auxiliary layer 120 may be in a range from about 5.0 eV to about 7.0 eV, for example, from about 5.2 eV to about 6.8 eV, from about 5.4 eV to about 6.8 eV, from about 5.4 eV to about 6.7 eV, from about 5.4 eV to about 6.5 eV, from about 5.4 eV to about 6.3 eV, from about 5.4 eV to about 6.2 eV, from about 5.4 eV to about 6.1 eV, from about 5.6 eV to about 7.0 eV, from about 5.6 eV to about 6.8 eV, from about 5.6 eV to about 6.7 eV, from about 5.6 eV to about 6.5 eV, from about 5.6 eV to about 6.3 eV, from about 5.6 eV to about 6.2 eV, from about 5.6 eV to about 6.1 eV, from about 5.8 eV to about 7.0 eV, from about 5.8 eV to about 6.8 eV, from about 5.8 eV to about 6.7 eV, from about 5.8 eV to about 6.5 eV, from about 5.8 eV to about 6.3 eV, from about 5.8 eV to about 6.2 eV, or from about 5.8 eV to about 6.1 eV.

As an example, the hole auxiliary layer 120 may include a hole injection layer close to the first electrode 110 and a hole transport layer close to the light emitting layer 130. In one or more embodiments, the HOMO energy level of the hole injection layer may range from about 5.0 eV to about 6.0 eV, from about 5.0 eV to about 5.5 eV, and from about 5.0 eV to about 5.4 eV, and the HOMO energy level of the hole transport layer may range from about 5.2 eV to about 7.0 eV, from about 5.4 eV to about 6.8 eV, from about 5.4 eV to about 6.7 eV, from about 5.4 eV to about 6.5 eV, from about 5.4 eV to about 6.3 eV, from about 5.4 eV to about 6.2 eV, or from about 5.4 eV to about 6.1 eV.

The material included in the hole auxiliary layer 120 is not particularly limited, and may include at least one of (e.g., at least one selected from among) carbon-based materials and/or any suitable combination thereof. The carbon-based materials may include, for example, poly(9,9-dioctyl-fluorene-co-N-(4-butylphenyl)-diphenylamine), poly(9,9-dioctyl-fluorene-co-N-(4-butylphenyl)-diphenylamine) (TFB), polyarylamine, poly(N-vinylcarbazole), poly(3,4-ethylenedioxylamine), poly(3,4-ethylenedioxythiophene) (PEDOT), poly(3,4-ethylenedioxythiophene) polystyrene sulfonate (PEDOT: PSS), polyaniline, polypyrrole, N,N,N′, N′-tetrakis(4-methoxyphenyl)-benzidine (TPD), 4-bis [N-(1-naphthyl)-N-phenyl-amino]biphenyl(4-bis [N-(1-naphthyl)-N-phenyl-amino]biphenyl(a-NPD), (4,4′,4″-tris [phenyl(m-tolyl)amino] triphenylamine) (m-MTDATA), 4,4′,4″-tris(N-carbazolyl)-triphenylamine (4,4′,4″-tris(N-carbazolyl)-triphenylamine (TCTA), 1,1-bis [(di-4-toylamino) phenylcyclohexane (TAPC), p-type or kind metal oxides (e.g. NiO, WO₃, MoO₃, and/or the like), and/or graphene oxides. But the present disclosure is not limited thereto.

In the hole auxiliary layer(s), the thickness of each layer may be appropriately or suitably selected.

For example, the thickness of each layer may be equal to or larger than about 10 nm, such as about 15 nm or more, or about 20 nm or less, and equal to or smaller than about 100 nm, such as about 90 nm or less, about 80 nm or less, about 70 nm or less, about 60 nm or less, or about 50 nm, but the present disclosure is not limited thereto.

The electron auxiliary layer 140 may be arranged between the light emitting layer 130 and the second electrode 150. The electron auxiliary layer 140 may include, for example, an electron injection layer, an electron transport layer, and/or a hole blocking layer, but the present disclosure is not limited thereto. As an example, the electron auxiliary layer 140 may be an electron transport layer.

The electron auxiliary layer 140 may include metal oxide nanoparticles surface-modified with organic acid. The metal oxide may be an oxide of a metal including Zn, Mg, Ca, Zr, W, Li, Ti, Y, Al, and/or any suitable combination thereof. As an example, the metal oxide may be represented by the following Formula 1.

Zn₁₋ₓMₓO Formula 1

In Formula 1, M may be Mg, Ca, Zr, W, Li, Ti, Y, Al, and/or any suitable combination thereof, and for example, may be Mg.

In Formula 1, x may be equal to or greater than about 0 and equal to or less than about 0.5, such as equal to or greater than about 0.01 and equal to or less than about 0.3, or equal to or greater than about 0.01 and equal to or less than about 0.15.

As an example, the metal oxide may include at least one of zinc oxide, zinc magnesium oxide, and/or any suitable combination thereof.

The average particle size or diameter of the metal oxide nanoparticles may be equal to or larger than about 1 nm, such as at least about 1.5 nm, at least about 2 nm, at least about 2.5 nm, or at least about 3 nm, and equal to or smaller than about 100 nm, such as at most about 90 nm, at most about 80 nm, at most about 70 nm, about 60 nm or less, about 50 nm or less, about 40 nm or less, about 30 nm or less, about 20 nm or less, about 10 nm or less, about 9 nm or less, about 8 nm or less, about 7 nm or less, about 6 nm or less, or about 5 nm or less.

The metal oxide nanoparticles may be neither rod-shaped nor nanowire-shaped.

The absolute value of the LUMO of the quantum dots may be smaller than the absolute value of the LUMO of the metal oxide (nanoparticles). The absolute value of the LUMO of the quantum dots may be greater than the absolute value of the LUMO of the metal oxide. The absolute LUMO value of the metal oxide may be at least about 2 eV, at least about 2.5 eV, at least about 3 eV, at least about 3.5 eV, or at least about 4 eV, and at most about 5 eV, at most about 4.5 eV, at most about 4 eV, at most about 3.5 eV, or at most about 3 eV.

The absolute HOMO value of the metal oxide may be at least about 5 eV, at least about 5.5 eV, at least about 6 eV, at least about 6.5 eV, or at least about 7 eV, and at most about 8 eV, at most about 7.5 eV, at most about 7 eV, at most about 6.5 eV, or at most about 6 eV.

The energy band gap of the metal oxide may be at least about 2 eV, at least about 2.5 eV, at least about 3 eV, at least about 3.5 eV, or at least about 4 eV, and at most about 5 eV, at most about 4.5 eV, at most about 4 eV, at most about 3.5 eV, or at most about 3 eV.

In a quantum-dot light emitting device (QD-LED), holes and electrons respectively injected from the first electrode 110 and the second electrode 150, after passing through common layers (e.g., an electron auxiliary layer such as an electron injection layer, an electron transport layer, and/or the like, and a hole auxiliary layer such as an hole injection layer, a hole transport layer, and/or the like), may meet each other in the light emitting layer 130 including quantum dots to form excitons, and then recombine to emit light.

The common layer may be provided between the light emitting layer 130 and the first electrode 110 or the second electrode 150 for smooth injection of holes or electrons by voltage application, and for example, an electron auxiliary layer such as an electron transport layer has sufficient electron mobility to efficiently transfer electrons from the second electrode 150 to the quantum-dot light emitting layer 130 such that the hole-electron balance in the light emitting layer 130 is obtained.

In one or more embodiments, the electron auxiliary layer has an appropriately or suitably deep HOMO energy level to sufficiently block or reduce holes coming from the quantum-dot emission layer 130.

As an example, the electron transport layer may include metal oxide nanoparticles. Although metal oxide nanoparticles have superior electron mobility than organic semiconductor materials that are widely utilized as the electron transport layer of an OLED, they may have a relatively high leakage current value due to easier hole transfer through defects in the nanoparticles, which may cause a decrease in the efficiency of quantum-dot light emitting devices (QD-LEDs).

In addition, organic substances originating from one or more suitable organic-inorganic precursors utilized in the synthesis of metal oxide nanoparticles may act as insulators on the surface of nanoparticles or between nanoparticles, reducing electron mobility, and may cause charging resulting from charge accumulation at the interface between the quantum-dot light emitting layer 130 and the electron transport layer, thereby causing a decrease in the brightness and lifetime of the quantum-dot light emitting devices (QD-LEDs).

In the light emitting device 100 according to one or more embodiments, the electron auxiliary layer 140 (e.g., electron transport layer) may include metal oxide nanoparticles surface-modified with organic acid.

Accordingly, the leakage current of the electron auxiliary layer 140 may be reduced and electron accumulation may be eliminated.

Organic acids chemically bond with metal ions, combinations of metal ions and oxygen or hydroxyl groups, or a combination thereof, on the surface of metal oxide nanoparticles, to passivate defects on the surface and desorb remaining organic substances on the surface, thereby providing higher conductivity and fewer defects.

Accordingly, the electron auxiliary layer 140 may improve the efficiency and lifetime of the quantum-dot light emitting device 100.

Organic acids may be acidic organic substances having functional groups that can bind to the surface of metal oxide nanoparticles, which may include, for example, RCOOH, RSO₂H, RSO₃H, ArOH, ArSH, RCH═NOH, RCH═C(OH)R′, RCONHCOR′, ArSO₂NH₂, ArSO₂NHR, RCH₂NO₂, R₂CHNO₂ and/or any suitable combination thereof. Here, R and R′ may be the same or different, and each of R and R′ may be independently hydrogen, a substituted or unsubstituted C1 (or C3) to C24 (or C40) aliphatic hydrocarbon group, and a C3 to C40 alicyclic group or a hydrocarbon group (i.e., a C1 (or C3) to C24 (or C40) alkyl group, a C1 (or C3) to C24 (or C40) alkenyl group, a C1 (or C3) to C24 (or C40) alkynyl group. and/or any suitable combination thereof. At least one R may not be hydrogen, and Ar may include a substituted or unsubstituted C6 to C20 aromatic hydrocarbon group (i.e., a C6 to C20 aryl group).

The organic acid has a molecular weight of equal to or greater than about 30 g/mol, for example, at least about 40 g/mol, at least about 50 g/mol, at least about 60 g/mol, at least about 70 g/mol, at least about 80 g/mol, at least about 90 g/mol, or at least 100 g/mol, and may be equal to or less than about 600 g/mol, such as at most about 500 g/mol, at most about 400 g/mol, or at most about 300 g/mol. The molecular weight of the organic acid may be in a range from about 30 g/mol to about 600 g/mol, such as, from about 50 g/mol to about 500 g/mol, from about 80 g/mol to about 400 g/mol, or from about 100 g/mol to about 300 g/mol.

The organic acid may have a pKa of equal to or greater than about 1, for example, at least about 1.5, at least about 2, or at least about 2.5, and equal to or less than about 5, such as at most about 4.5, at most about 4, or at most about 3.5. The pKa of the organic acid may be in a range from about 1 to about 5, such as from about 1.5 to about 4.5, from about 2 to about 4, or from about 2.5 to about 3.5.

Examples of organic acids having the desired or suitable ranges of molecular weight and pKa may include citric acid, acetic acid, oxalic acid, sulfonic acid, and/or any suitable combination thereof.

In particular, sulfonic acid with a molecular weight of about 600 g/mol or less may be utilized.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within +30%, 20%, 10%, 5% of the stated value.

Also, any numerical range recited herein is intended to include all subranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Further, the use of “may” when describing embodiments of the present disclosure refers to “one or more embodiments of the present disclosure.”

The light emitting device, electronic apparatus or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although the embodiments of the present disclosure have been described, it is understood that the present disclosure should not be limited to these embodiments, but one or more suitable changes and modifications can be made by one ordinary skilled in the art within the spirit and scope of the present disclosure as defined by the following claims and equivalents thereof.

What is claimed is:

1. A method of manufacturing a display device, the method comprising:
manufacturing a display panel comprising a plurality of quantum-dot light emitting devices;
exposing the display panel to resin fumes; and
adhering a protective film on the display panel.

2. The method of claim 1, wherein the resin fumes comprise at least one of acrylic acid, acetic acid, methacrylic acid, or isobornyl methacrylate.

3. The method of claim 2, wherein the resin fumes comprise at least one of acrylic acid or methacrylic acid.

4. The method of claim 1, wherein the protective film comprises a transparent glass.

5. The method of claim 1, wherein the adhering of the protective film comprises arranging a sealant adjacent to at least one of an edge of the display panel or an edge of the protective film.

6. A display device comprising:
a display panel comprising a plurality of quantum-dot light emitting devices, the display panel comprising a resin adsorbed on the quantum-dot light emitting devices via resin fumes;
a protective film on the display panel; and
a sealant between the display panel and the protective film and adjacent to edges of the display panel and the protective film.

7. The display device of claim 6, wherein the resin fumes comprise at least one of acrylic acid, acetic acid, methacrylic acid, or isobornyl methacrylate.

8. The display device of claim 7, wherein the resin fumes comprise at least one of acrylic acid or methacrylic acid.

9. The display device of claim 6, wherein the protective film comprises a transparent glass.

10. The display device of claim 6, wherein the quantum-dot light emitting devices each comprise an electron auxiliary layer surface-modified with the resin.

11. A method of manufacturing a display device, the method comprising:
manufacturing a display panel comprising a plurality of quantum-dot light emitting devices;
exposing the display panel to resin fumes, and
sealing the display panel with a sealant.

12. The method of claim 11, wherein the resin fumes comprise at least one of acrylic acid, acetic acid, methacrylic acid, or isobornyl methacrylate.

13. The method of claim 12, wherein the resin fumes comprise at least one of acrylic acid or methacrylic acid.

14. The method of claim 12, wherein the sealing of the display panel comprises adhering a protective film on the display panel.

15. A display device comprising:
a display panel comprising a plurality of quantum-dot light emitting devices;
a protective film on the display panel; and
a sealant between the display panel and the protective film and adjacent to edges of the display panel and the protective film,
wherein the display panel and the protective film are spaced from each other via an air layer.

16. The display device of claim 15, wherein the display panel comprises a resin adsorbed on the quantum-dot light emitting devices via resin fumes.

17. The display device of claim 16, wherein the resin fumes comprise at least one of acrylic acid, acetic acid, methacrylic acid, or isobornyl methacrylate.

18. The display device of claim 17, wherein the resin fumes comprise at least one of acrylic acid or methacrylic acid.

19. The display device of claim 15, wherein the protective film comprises a transparent glass.

20. The display device of claim 16, wherein the quantum-dot light emitting devices each comprise an electron auxiliary layer surface-modified with the resin.
